(19) United States
(12) Patent Application Publication
(10) Pub. No.: US 2026/0333564 A1
(43) Pub. Date: Oct. 22, 2026

(54) PRINTED CIRCUIT BOARDS WITH INTEGRATED COOLING PLATES

(71) Applicant: Toyota Motor Engineering & Manufacturing North America, Inc., Plano, TX (US)

(72) Inventors: Danny J. Lohan, West Bloomfield, MI (US); Shailesh N. Joshi, Ann Arbor, MI (US); Ercan M. Dede, Ann Arbor, MI (US)

(73) Assignee: Toyota Motor Engineering & Manufacturing North America, Inc., Plano, TX (US)

(21) Appl. No.: 19/184,823

(22) Filed: Apr. 21, 2025

(51) Int. Cl. H05K 1/02

(52) U.S. Cl. CPC H05K 1/0203; H05K 2201/0753

(57) ABSTRACT

In one embodiment, an electronic assembly comprising a printed circuit board (PCB), the PCB comprising a PCB surface; one or more heat generating devices coupled to the PCB surface, the one or more heat generating devices separated from one another by an insulation layer; and PCB trace connected to at least one of the one or more heat generating devices; and a cooling plate directly coupled to the PCB, the cooling plate comprising: a porous layer directly coupled to at least one portion of the PCB; and a covering cap, wherein the electronic assembly is configured to passively transfer heat from the heat generating devices to the covering cap.

### BACKGROUND

Printed circuit boards (PCB) are used in nearly all electronic products today. PCBs are generally flat surfaces with conductive pathways (traces) for mounting and connecting electronic components together in an electrical circuit. A PCB may include conductive and insulating layers. PCBs can be single sided with one copper layer, double-sided with two copper layers on both sides of one substrate layer, or multi-layered (stacked layers of substrate with copper plating sandwiched between each layer and on the outside layers). Electronic components mounted on PCBs may generate heat and are thus referred to herein as heat generating devices.

Heat generating devices, such as power semiconductor devices, may be coupled to a cooling plate to remove heat and lower the maximum operating temperature of the heat generating device. Heat generating devices may also be cooled by active cooling, for example by fans or forced air. Vapor chambers are commercially available heat spreading technologies which exist in many shapes and forms. Their primary function is to move heat from a small location through the entirety of its package and may be used to remove heat from heat generating devices.

Current cooling systems may not be able to adequately remove heat from the heat generating devices. For example, SiC power electronic devices may generate significant heat that current cooling solutions cannot cool.

Accordingly, alternative cooling solutions and improvements for cooling heat generating devices and components may be desired.

### BRIEF SUMMARY

In one embodiment, a printed circuit board (PCB), the PCB includes a PCB surface, one or more heat generating devices coupled to the PCB surface, wherein the one or more heat generating devices are separated from one another by an insulation layer. The PCB also includes a PCB trace connected to at least one of the one or more heat generating devices, and a vapor chamber directly coupled to the PCB. The vapor chamber includes a porous layer directly coupled to at least one portion of the PCB; and a covering cap, wherein the electronic assembly is configured to passively transfer heat from the heat generating devices to the covering cap.

In another embodiment, a method for a low temperature porous layer creation process includes mixing a metal formate with a solvent to form a metal formate solution, adjusting a metal formate concentration in the metal formate solution, collecting a refined metal formate solution, mixing the refined metal formate solution with metal particles to form a metal particle slurry, applying the metal particle slurry to a substrate, and sintering the metal particle slurry onto the substrate.

In another embodiment, an integrated PCB cooling plate includes a porous layer directly coupled to one or more heat generating devices, wherein the porous layer is formed by a low temperature porous layer creation process.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a cross-sectional side view of a PCB attached to a vapor chamber.

FIG. 2 illustrates a cross-sectional side view of an example electronic assembly with an integrated PCB cooling plate, according to one or more embodiments described and illustrated herein.

FIG. 3A illustrates a top view of the example electronic assembly with the PCB without the integrated cooling plate installed, according to one or more embodiments described and illustrated herein.

FIG. 3B illustrates a side view of the example electronic assembly with the PCB without the integrated cooling plate installed, according to one or more embodiments described and illustrated herein.

FIG. 4A illustrates a top view of an example electronic assembly with the PCB with an integrated cooling plate, according to one or more embodiments described and illustrated herein.

FIG. 4B illustrates a side view of an example electronic assembly with the PCB with an integrated cooling plate, according to one or more embodiments described and illustrated herein.

FIG. 5 illustrates a top cross-sectional view of an example electronic assembly with the PCB with an integrated cooling plate, according to one or more embodiments described and illustrated herein.

FIG. 6A illustrates a side cross sectional view of the various components of an example unassembled example electronic assembly with the PCB with an integrated cooling plate, according to one or more embodiments described and illustrated herein.

FIG. 6B illustrates an assembled example electronic assembly with the PCB with an integrated cooling plate, according to one or more embodiments described and illustrated herein.

FIG. 7A illustrates the layers in a conventional PCB with a vapor chamber.

FIG. 7B illustrates the layers in example electronic assembly with the PCB with an integrated cold, according to one or more embodiments described and illustrated herein.

FIG. 8 illustrates a method for forming a porous layer that for use in the example electronic assembly with the PCB with an integrated cooling plate, according to one or more embodiments described and illustrated herein.

FIG. 9A presents a scanning electron microscope (SEM) image of a porous layer depicting a porous layer formed without using a refined metal formate-solvent solution as described in FIG. 8, according to one or more embodiments described and illustrated herein.

FIG. 9B presents another scanning electron microscope (SEM) image of a porous layer depicting a porous layer formed by using a refined metal formate-solvent solution as described in FIG. 8, according to one or more embodiments described and illustrated herein.

### DETAILED DESCRIPTION

A challenge with vapor chamber technology is overcoming the thermal resistance between the metal surface and the heat generating device. Thermal interface materials (TIMs), like gap pads or thermal grease, are typically used to minimize the thermal resistance between the two surfaces; however, TIMs add their own inherent thermal resistance as well as thickness to the vapor chamber and heat generating devices.

Compactness of a PCB is important as it is needed for space-saving and miniaturization, especially in modern applications for miniature devices. A minimal form-factor allows a PCB to fit in smaller electronic assemblies and packages. The present disclosure provides integrated PCB passive cooling plates that allow an improvement to and reduce the form factor of a PCB by removing at least one TIM layer while maintaining or improving thermal performance.

Embodiments of the present disclosure provide an electronic assembly with an integrated PCB passive cooling plate that places a porous layer such as a wick layer in direct contact with heat generating devices to reduce the thickness and size of the electronic assembly. Fabrication of porous layers, e.g., porous metal layers, and bonding of such layers to heat generating devices may be difficult or result in damage of the heat generating devices. In some embodiments, a low temperature sintering process is used to fabricate or bond the porous layer onto heat generating devices or other components.

Various embodiments of electronic cooling assemblies are described in detail below.

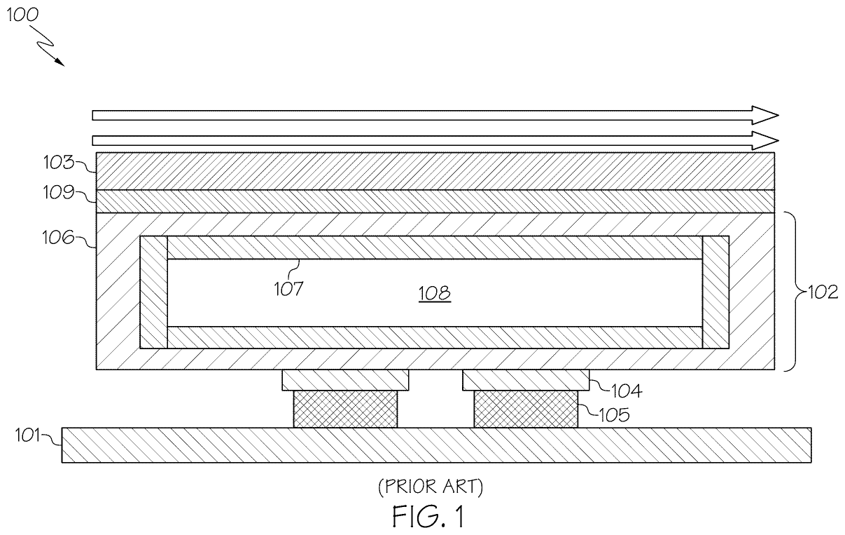

FIG. 1 illustrates a cross-sectional side view of a prior art assembly 100 comprising a PCB 101 attached to a vapor chamber 102. A conventional PCB with a vapor chamber 100 includes a PCB 101 connected to a vapor chamber 102 to cool the PCB 101. The vapor chamber 102 may in turn be coupled to an external cooler 103, e.g., metal fins cooled by a fan, which is placed on the vapor chamber 102 via a TIM 109. The PCB 101 generally includes heat generating devices 105. The heat generating devices 105 may include a range of electrical and electronic components. The heat generating devices 105 are coupled to the vapor chamber 102 via TIM 104. The TIM 104 therefore is the interface between the vapor chamber 102 and the heat generating devices 105 on the PCB 101.

The vapor chamber 102 typically has thermally conductive walls 106, which includes porous layer 107. The porous layer 107 and the thermally conductive walls 106 may be folded over to form a cavity 108 that defines the vapor chamber. This cavity 108 can be filled with coolant up to a certain volume ratio. Heat is applied, e.g., by the heat generating devices 105, to a heating side (the side closest to the heat generating devices 105, e.g., the bottom of the vapor chamber 102) of the vapor chamber 102 where the coolant will evaporate and rise to the evaporator side (the side of the vapor chamber 102 furthest away from the heat generating devices 105, e.g., the top of the vapor chamber 102). Vapor will rise from the evaporator side where the external cooler 103 may be used to remove the heat. The vapor will condense and then passively travel through the porous layer 107 and move back towards the heating side of the vapor chamber 102. The vapor chamber 102 is not in direct contact with the PCB 101 but connects via a TIM 104 to the heat generating devices 105.

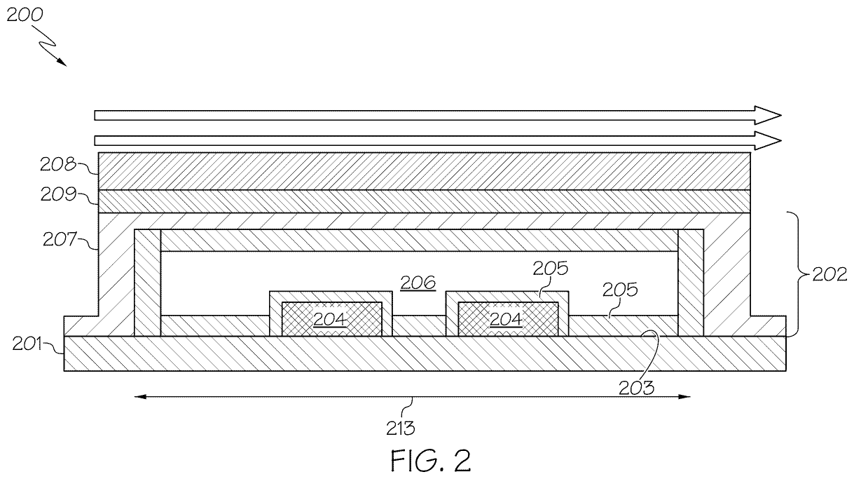

The TIM 104 primarily reduces thermal resistance between the heat generating devices 105 and the vapor chamber 102, for example by filling in air gaps on the surfaces of the heat generating devices 105 and the vapor chamber 102. However, while providing an overall net reduction in thermal resistance, the TIM 104 adds its own intrinsic thermal resistance. The intrinsic thermal resistance of the TIM 104 depends on the thickness of the TIM 104 and the thermal conductivity of the materials that make up the TIM 104. TIMs therefore should be as thin as possible and made of high thermally conductive material. However, a superior solution is to remove the TIM 104 and directly connect the heat generating devices 105 to the cooling chamber, e.g., the vapor chamber 102 or other types of cooling plates without any interfacing barriers. FIG. 2 describes one embodiment of directly connecting the cooling material to a cooling plate by integrating the cooling plate with the PCB 101.

FIG. 2 illustrates a cross-sectional side view of an electronic assembly 200 with an integrated PCB cooling plate according to one or more embodiments described and illustrated herein. The integrated PCB cooling plate electronic assembly 200 includes a PCB 201 bonded directly with a cooling plate 202, e.g., a vapor chamber or passive cooler. The PCB 201 includes a PCB surface 203 and may include one or more heat generating devices 204 coupled to the PCB surface 203. The heat generating devices 204 may include a range of electrical and electronic components such as passive, active, electromechanical, power, signal and communication, protection, processing, memory and storage, communication, security, and I/O controller components.

The one or more heat generating devices 204 can include low temperature devices and high temperature devices. Low temperature devices may refer to heat generating devices that produce less total heat energy over a period or produce heat of a lower temperature over a period than the amount and temperature of heat produced by the high temperature devices. Low temperature devices may also refer to devices that cannot tolerate the high temperatures of high temperature devices or can only operate in lower temperatures than high temperature devices.

In embodiments, a porous layer 205 is deposited direction onto both the surfaces of the one or more heat generating devices 204 and the PCB surface 203. The heat generating devices 204 may be separated from each other by the porous layer 205, or by an insulation layer (not shown), e.g., an insulation layer made up of silicone or other electrically insulating material. The porous layer 205 may include portions of the porous layer 205 that are in contact with the PCB surface 203 but that do not cover the heat generating devices 204. Applying the porous layer 205 directly onto the one or more heat generating devices 204 and the PCB surface 203 eliminates the needs for the TIM 104 shown in FIG. 1, thereby reducing both the thermal resistance and size of the assembly.

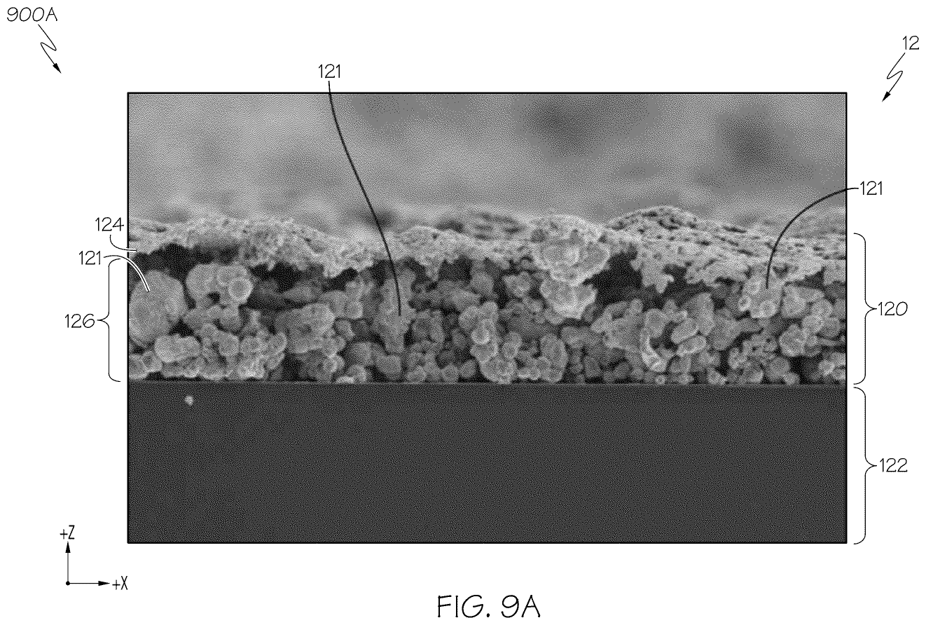

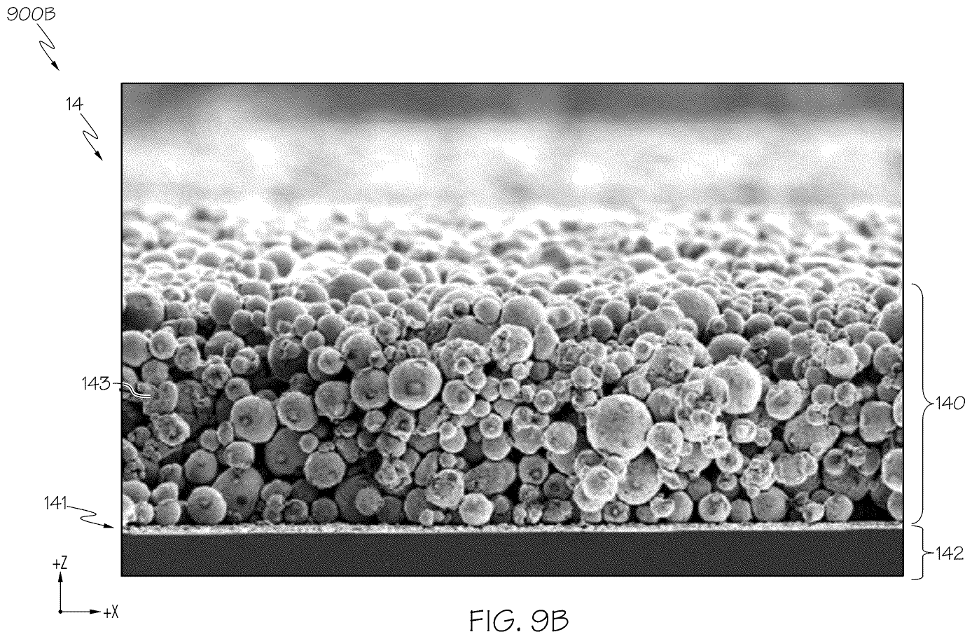

The porous layer 205 may include or be made up of a porous wick material. The porous wick material may consist of substances that have been melted or partially melted through additive manufacturing or through the processes described in FIGS. 8-9B. For example, it may include a partially sintered powder with a relatively high porosity. The porous layer may be a material with interconnected pores that facilitates the movement of fluids through capillary action.

The porous layer 205 may be folded over itself to form an enclosed volume 206. The enclosed volume 206 may include a liquid or a thermal coolant or have one added to it. For example, a dielectric thermal coolant. Additionally, the porous layer 205 may be coupled to a covering cap 207. In some embodiments, the covering cap 207 includes a predisposed porous layer 205 that is then coupled with the porous layer 205 that is directly coupled to the PCB 201 or the porous layer 205 coupled to the heat generating devices 204, while in other embodiments, the porous layer 205 is made up of one piece. While the direct coupling of the porous layer 205 may include placing a layer on top of a portion of the PCB 201 (which may include placement directly on the heat generating devices 204) it may also include coating at least one portion of the PCB 201 with a porous layer, where the coating may be uniform or may be patterned.

In some embodiments, the electronic assembly 200 may include the covering cap 207 directly bonded to the PCB 101 via the PCB surface 203. The covering cap 207 may be coupled to the PCB surface 203 via a copper patterning, as a non-limiting example. The coupling of the covering cap 207 to the PCB surface 203 may be achieved by sintering the covering cap to copper patterning on the PCB surface 203, for example. In some embodiments, the covering cap 207 is a metallic cap, for example made of copper or another metal or metal alloy.

In some embodiments, the electronic assembly 200 is configured to passively transfer heat from the heat generating devices 204 to the covering cap 207, and out of the covering cap 207, where heat is generated by the heat generating devices 204 and dissipates through the porous layer 205 and through the covering cap 207. In some embodiments, active forms of external cooling 208 may be deployed, e.g., air or liquid cooling to extract heat from the electronic assembly 200. In some embodiments, the electronic assembly 200 is a completely passive cooling assembly, but in others an external cooler, such as the external cooling 208, e.g., air external cooler may be deployed that is coupled to the metallic over 207 via TIM 209 to actively remove heat that emanates from the covering cap 207 and cool the PCB 201 with surface mount active and passive devices. A cooling plate area 213 represents a side of the area covered formed by the space covered by the porous layer 205 and the covering cap 207, where the heat generating devices 204 could be placed.

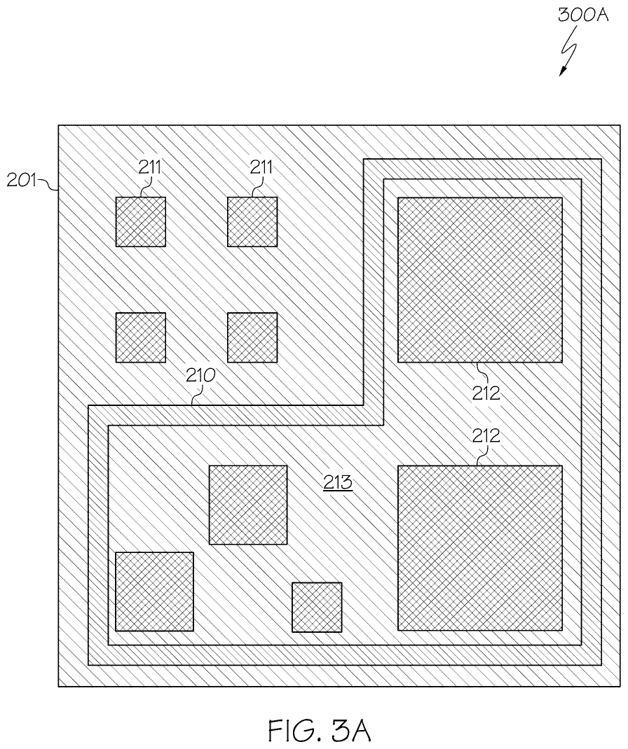

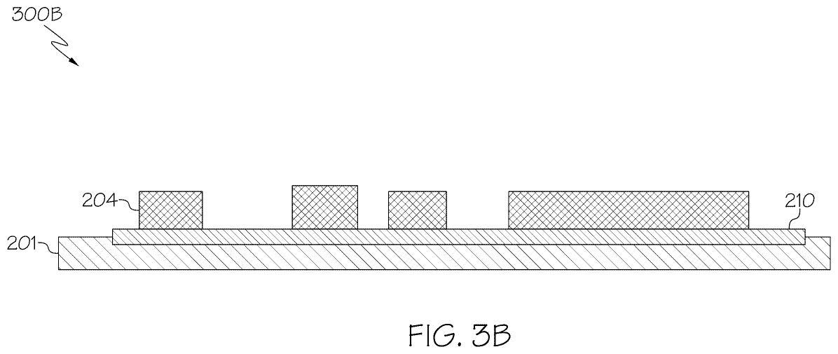

FIG. 3A illustrates a top view 300A of the example electronic assembly 200 including PCB 201 without the cooling plate according to one or more embodiments described and illustrated herein. The example PCB 201 includes one or more heat generating devices (e.g., heat generating devices 204) that include low temperature heat generating devices 211 and high temperature heat generating devices 212. For example, the high temperature heat generating devices 212 such as wide bandgap devices are typically smaller in footprint than silicon devices but tolerate a much higher operating temperature. These may be combined on the PCB 201 with low temperature heat generating devices 211 such as silicon devices and passive components such as capacitors and inductors which do not tolerate temperatures much higher than 100 °C.

As described in relation to FIG. 2, the cooling plate 202, and in particular the covering cap 207 may be bonded to the PCB 201 via the PCB surface 203 by using copper patterning 210. The copper patterning 210 on the PCB surface 203 may define the cooling plate area 213 of the cooling plate 202 or the covering cap 207. Some heat generating devices 204 may be within the cooling plate area 213 and some may be outside of it. For example, in some designs, the cooling plate area 213 (and its associated cooling plate) may cover the high temperature heat generating devices 212 and exclude the low temperature heat generating devices 211, e.g., for designs that prioritize the cooling of the high temperature heat generating devices 212.

FIG. 3B illustrates a side view 300B of the example electronic assembly 200 including the PCB with an integrated cooling plate without the cooling plate installed, according to one or more embodiments described and illustrated herein. The example electronic assembly 200 is depicted with the PCB 201, the one or more heat generating devices 204 and the copper patterning 210 as described in FIG. 3A.

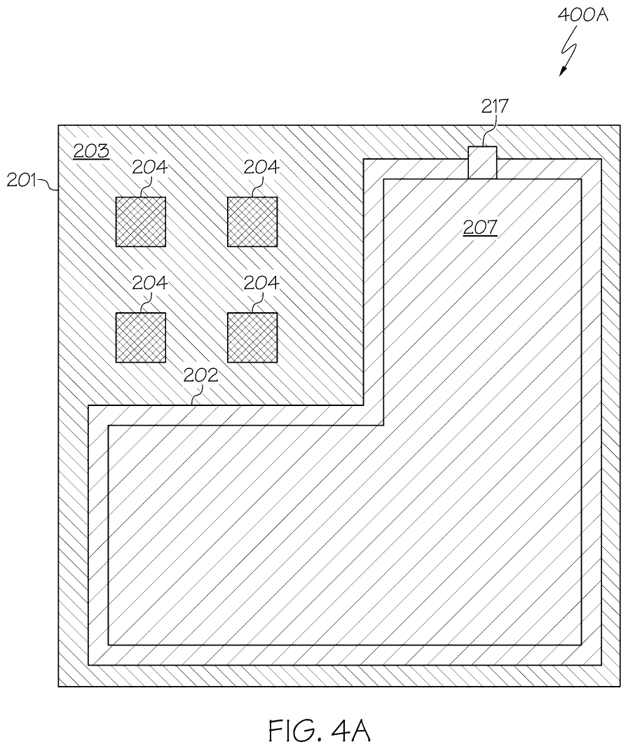

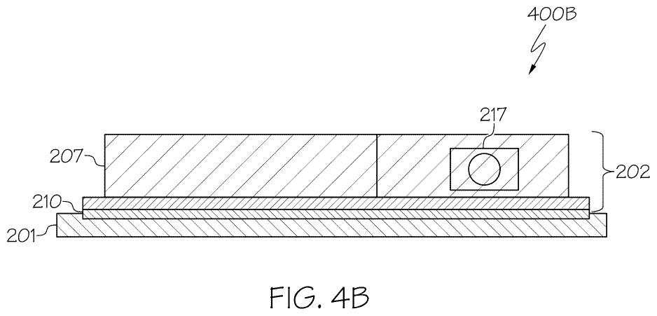

FIG. 4A illustrates a top view 400A of an example electronic assembly 200 with a PCB with an integrated cooling plate according to one or more embodiments described and illustrated herein. The cooling plate 202 is depicted with the covering cap 207 covering all components under it, which includes a portion of the PCB 201 and one or more heat generating devices 204. Other heat generating devices 204 are positioned outside of the cooling plate 202 and are exposed on the PCB surface 203. In some embodiments, the covering cap 207 includes a port 217 for filling the covering cap 207 with a coolant or to allow evacuation of the covering cap 207.

In some embodiments, it may be appropriate to spread heat across the entire PCB surface 203, leading to an implementation where the cooling plate 202 covers the entire PCB surface 203. In some embodiments, the cooling plate may be designed to cover a portion of the PCB surface and spreading heat around specific heat generating devices 204, e.g., high temperature heat generating devices 212 only. Copper may be patterned on the surface of the PCB in the shape of the cooling plate as is depicted by the copper patterning 210 of FIGS. 3A-3B, and the cooling plate may be bonded directly to the PCB 201 on some or all the copper patterning 210.

FIG. 4B illustrates a side view 400B of an example electronic assembly 200 with a PCB with an integrated cooling plate according to one or more embodiments described and illustrated herein. The cooling plate 202 can be seen depicted with its covering cap 207 with a port 217, where the covering cap 207 is bonded via the copper patterning 210 to the surface of the PCB 201.

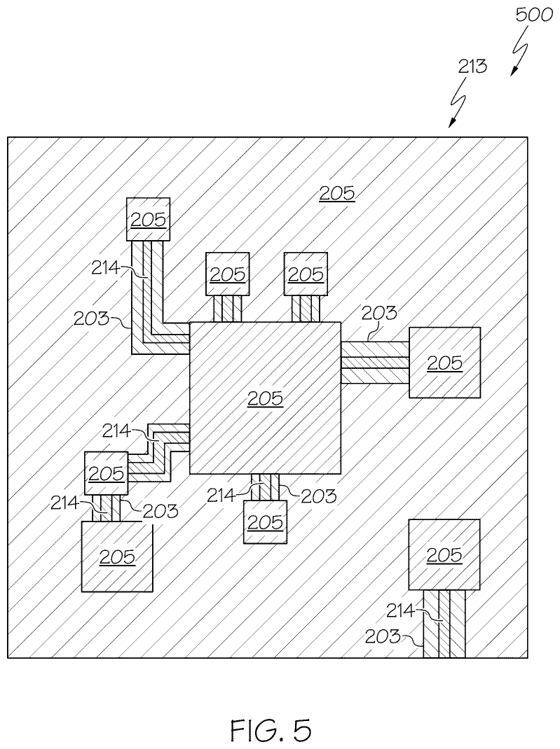

FIG. 5 illustrates a top cross-sectional view 500 of the cooling plate area 213 of an electronic assembly 200 with a PCB with an integrated cooling plate according to one or more embodiments described and illustrated herein. As described herein electronic assembly 200 may include a PCB trace 214 on the PCB 201, the PCB trace 214 is a conductive pathway embedded in the PCB that electrically connects various components, e.g., the heat generating devices 204, together. The PCB trace 214 is generally made of copper or with a protective coating.

Depicted in the view 500 is the porous layer 205 that is directly covering the heat generating devices 204. Additionally depicted is the porous layer 205 that covers other portions of the PCB surface 203 that do not include the heat generating devices 204. The porous layer 205 avoids the PCB trace 214 to avoid electrically shorting the PCB trace 214.

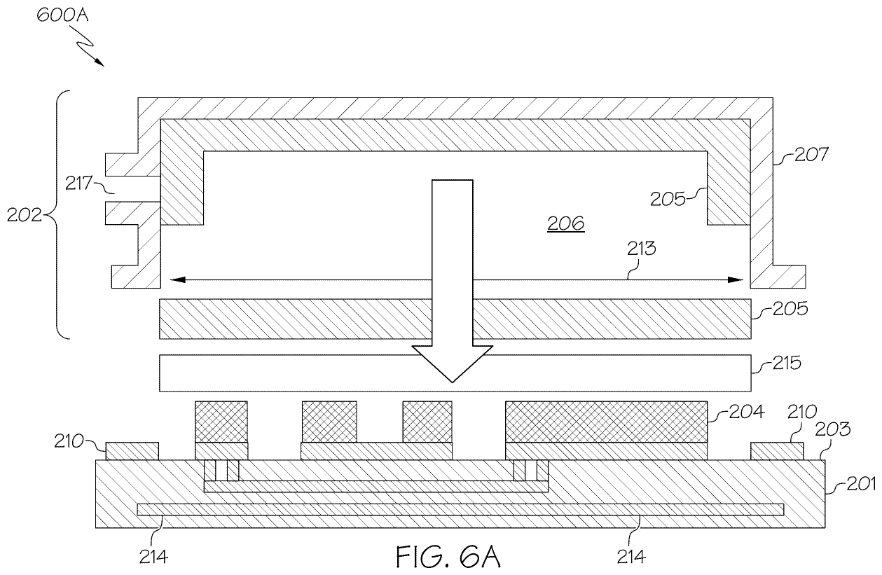

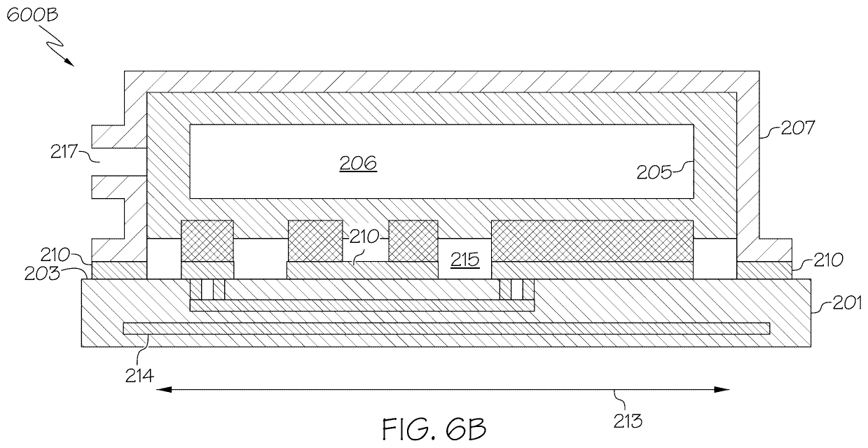

FIG. 6A illustrates a side cross sectional view 600A of the various components of an unassembled electronic assembly 200 with a PCB with an integrated cooling plate according to one or more embodiments described and illustrated herein. The components of the electronic assembly 200 include a PCB 201, heat generating devices 204 connected to each other via a PCB trace 214 embedded (at least partially) in the PCB 201. The PCB 201 includes a PCB surface 203 with copper patterning 210. In some aspects, the porous layer 205 avoids the PCB trace 214 or the copper patterning 210, and in some aspects, the porous layer 205 distribution is optimized by using topology optimization to enhance thermal performance. An insulation layer 215 may also be included, for example an insulation layer made from electrically insulating material such as silicone, to electrically isolate the PCB surface 203 and electrically isolate the heat generating devices 204. Alternatively, electrical insulation can also be achieved by coating the porous layer 205 with an insulating material, or by creating porous structures around existing conductive paths of the PCB trace 214. The components of the cooling plate 202 include a covering cap 207 with its own porous layer 205 predisposed within the covering cap 207 that couples with the porous layer 205 on the PCB 201 or the heat generating devices 204 when the covering cap is coupled to the PCB 201. The covering cap is shown with a port 217 the allows evacuation of gases or liquids from the electronic assembly 200 and can be used to fill the electronic assembly 200 with a coolant. An enclosed volume 206 is formed withing the porous layer 205 when the covering cap 207 is coupled to the PCB 201. The covering cap 207 is coupled to the PCB 201 via copper patterning 210.

FIG. 6B illustrates a side cross sectional view 600B of an electronic assembly 200 with a PCB with an integrated cooling plate according to one or more embodiments described and illustrated herein. A low temperature sintering process as described in FIGS. 8-9B may be used to construct the porous layer 205, e.g., a wick, directly on the heat generating devices 204 or on the insulation layer 215. Furthermore, the covering cap 207 (with an internal porous layer 205, e.g., a wick) may be coupled to the PCB 201 by being sintered to the copper patterning 210 on the PCB 201.

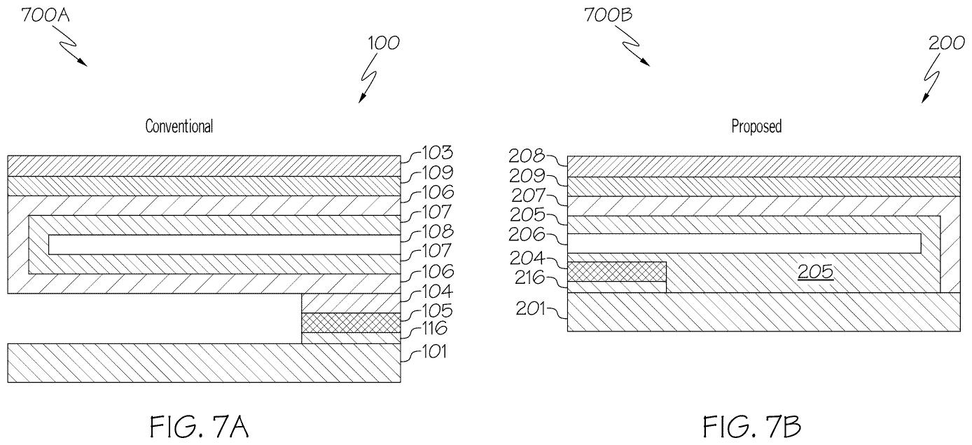

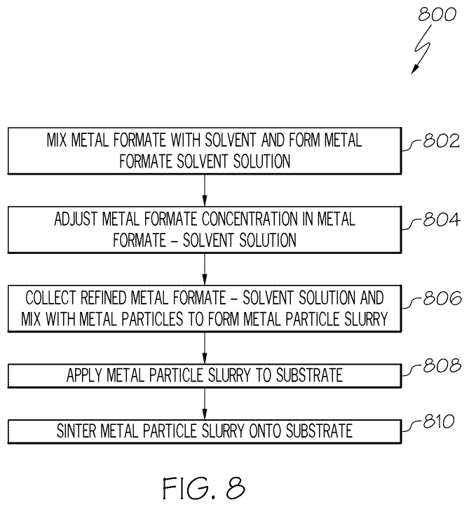

FIGS. 7A-7B illustrate layers of a conventional PCB with a vapor chamber 100 and layers of the electronic assembly 200 with a PCB with an integrated cooling plate, respectively, as simulated by a computer simulation. Simulation studies conducted using COMSOL multi-physics (a simulation software package used for analyzing and solving complex engineering and physics problems) compare the thermal benefits of these two designs. A cross section of each assembly is constructed (700A representing the conventional PCB with a vapor chamber 100 and 700B representing the electronic assembly 200 with a PCB with an integrated cooling plate) and these assemblies are modeled assuming radial symmetry.

In the simulation a total heat load of 30 W is applied in the device area (for each model) and a convective heat transfer coefficient of 400 W/m2K was applied at the condenser side (the side of a porous layer adjacent to the heat generating devices). Conjugate heat transfer simulations are solved to generate results representing the steady state temperature for both configurations. A reduction in temperature was observed for the electronic assembly 200 model 700B in its more compact form and fewer layers with a maximum temperature of 94 °C as compared to the maximum temperature of 96 °C of 700 A.

The layers in a conventional PCB with a vapor chamber 100 may include a PCB 101 layer, a bonding agent 116 layer that bonds the PCB 101 to a heat generating device 105. Above the heat generating device 105 is a TIM 104 layer that couples to a metallic walls 106 layer. Inside the metallic walls 106 layer is a porous layer 107 folded on itself to form a cavity 108. The metallic walls 106 layer surrounds the porous layer 107. On top of the metallic walls 106 is the TIM 109 that is coupled to an external cooler 103.

The layers in the electronic assembly 200 as simulated include the PCB 201 bonded via a bonding agent 216 to a heat generating device 204 which in turn is bonded to a porous layer 205. The porous layer 205 folds on itself to form and surround an enclosed volume 206 layer. Above the porous layer 205 is the covering cap 207 layer, e.g., a copper metallic cover, and above that a TIM 209 layer that bonds to external cooling 208.

FIGS. 8-9B generally describe porous layers and the process to create porous layer, e.g., the porous layer 205, according to one or more embodiments described and illustrated herein. FIG. 8 illustrates a method 800 for forming a porous layer, e.g., the porous layer 205 for use in an electronic assembly 200 with a PCB with an integrated cooling plate according to one or more embodiments described and illustrated herein.

The porous layers, e.g., porous metal layers, are formed by sintering a slurry layer that includes metal particles and metal formate. That is, the porous layers are sintered metal particle-metal formate slurry layers (metal-metal formate slurry layers(s)), where the term “sinter” or “sintered” as used herein refers to heating a slurry layer with metal particles mixed with a metal formate-solvent solution such that the metal formate chemically reduces and forms bonds between the metal particles without the metal particles melting. In some variations, the sintered metal-metal formate slurry layers are sintered without pressure, other than atmospheric pressure, applied to the metal-metal formate slurry layers during the sintering process.

The slurry is synthesized such that a uniform sintered metal-metal formate slurry layer is provided. And as used herein, the phrase “uniform sintered metal-metal formate slurry layer” refers to sintered metal-metal formate slurry layer without a delaminated layer of excess reduced metal formate. Accordingly, the porous layers according to the teachings of the present disclosure have a generally uniform and smooth outer surface and a generally uniform particle packing density. In some variations, the slurry is synthesized such that the amount of metal formate in the slurry is carefully controlled, e.g., reduced, such that sufficient metal formate is present for sintering of the metal particles together and yet excess metal formate is not present to form delaminated layers of reduced metal formate in or on a sintered metal-metal formate slurry layer.

In some variations, the metal-metal formate slurry is sintered at low temperatures to form a porous layer. Stated differently, porous layers, e.g., that include copper, may refer to low temperature sintered porous layers. As used herein, the phrase “low-temperature sintered” refers to a temperature used to form a sintered metal-metal formate slurry layer that is at least 100 °C less than a temperature used to sinter the same metal particles according to traditional sintering techniques.

The method 800 includes mixing a metal formate with a solvent to form a metal formate-solvent solution at block 802.

The method 800 continues at block 804 to adjust the content (concentration) of the metal formate in the metal formate-solvent solution to form a refined metal formate-solvent solution.

As used herein, “refined metal formate-solvent solution” refers to a metal formate-solvent solution with a concentration of metal formate such that low temperature sintering of a metal particle slurry layer (formed from a plurality of metal particles and mixed with the refined metal formate-solvent solution), results in a sintered metal-metal formate slurry layer with less than 10 percent by volume excess reduced metal formate. And as used herein, the phrase “excess reduced metal formate” refers to reduced metal formate in a sintered metal-metal formate slurry layer that is not between and bonded to adjacent metal particles. The phrase “percent by volume” is a comparison of the volume of excess reduced metal formate to the volume of metal particles in a given sintered metal-metal formate layer. For example, in some variations, a refined metal formate-solvent solution results in a slurry layer less than 5% (by volume) excess reduced copper formate sintered metal-metal formate. And in some variations, a sintered metal-metal formate slurry layer has less than 2% (by volume) excess reduced metal formate, e.g., less than 1% by volume of excess reduced copper formate.

In some variations, the concentration of metal formate in the metal formate-solvent solution is reduced, e.g., using a filtering technique such as vacuum filtration, centrifugal filtration, gravity filtration, centrifugal filtration, granular filtration, mechanical filtration, or multilayer filtration, among others. Non-limiting examples of the metal formate include copper formate (C2H2CuO4), iron formate (C2H8FeO6), silver formate (CHAgO2), and aluminum formate (Al(HCOO)3), among others, and non-limiting examples of the solvent include isopropanolamine, cyclohexylamine, n-octyl amine, among others.

The method 800 continues at block 806, where the refined metal formate-solvent solution is collected and mixed with metal particles to form a metal particle slurry, e.g., a metal-metal formate slurry.

The metal particle slurry is applied to a substrate at block 808.

The metal particle slurry is sintered onto the substrate at block 810. Non-limiting examples of the metal particles include copper particles, copper alloy particles, iron particles, iron alloy particles, silver particles, silver alloy particles, aluminum particles, and aluminum alloy particles, among others. And non-limiting examples of the substrate can include substrates formed from semiconductor materials, metals, alloys, polymers, ceramics, and glass, among others.

In some variations, the metal-metal formate slurry is sintered at low temperatures to form a porous layer, e.g., the porous layer 205. Stated differently, porous copper layers according to the teachings of the present disclosure are low temperature sintered porous layers, e.g., porous copper layers or porous metal layers. As used herein, the phrase “low-temperature sintered” refers to a temperature used to form a sintered metal-metal formate slurry layer according to the teachings of the present disclosure that it is at least 100 °C less than a temperature used to sinter the same metal particles according to traditional sintering techniques. Accordingly, the porous layers described herein can be sintered at temperatures that are lower than traditional sintering temperatures for known porous layers. For example, slurries formed from copper particles and copper formate are traditionally sintered at temperatures equal to or greater than 400 °C and such high sintering temperatures can damage substrates of heat generating devices and/or heat generating devices to which such a porous copper layer is sintered (bonded) to. For example, sintering temperatures of 400 °C and above can damage a semiconductor device to which a porous copper layer is sintered to. Therefore, in some embodiments, slurries formed from copper particles and copper formate are sintered at temperatures of 300 °C or less.

FIGS. 9A-9B depict scanning electron microscope (SEM) images 900A and 900B of a porous layer. In FIG. 9A, a porous copper layer 12 formed without using a refined copper formate-solvent solution as described in FIG. 8 is shown by image 900A.

In FIG. 9B a porous copper layer 14 formed with using a refined copper formate-solvent solution according to teachings of the present disclosure is shown by image 900B.

The porous copper layer 12 of FIG. 9A includes a sintered copper-copper formate slurry layer 120 on a substrate 122 in the form of a gold coated silicon wafer and the porous copper layer 14 of FIG. 9B includes a sintered copper-copper formate slurry layer 140 sintered onto an interface layer 141 on a substrate 142 in the form of a gold coated silicon wafer. The sintered copper-copper formate slurry layer 140 can be sintered directly onto the substrate 142, i.e., the interface layer 141 is not required.

The metal particles in a sintered slurry layer can be selected to provide a porous layer with a desired porosity, desired value of heat transfer or desired value of electrical conductivity. For example, the metal particles can be copper particles, copper alloy particles, aluminum particles, or aluminum alloy particles, among others. Also, the metal particles can be micron-size particles with have an average diameter between about 100 nanometers (nm) and about 500 micrometers (μm). In some variations, the metal particles have an average diameter between about 100 nm and about 200 nm, between about 200 nm and about 300 nm, between about 300 nm and about 400 nm, between about 400 nm and about 500 nm, between about 500 nm and about 600 nm, between about 600 nm and about 700 nm, between about 700 nm and about 800 nm, between about 800 nm and about 900 nm, between about 900 nm and about 1000 nm, between about 1000 nm and about 10 μm, between about 10 μm and 50 μm, between about 50 μm and 100 μm, between about 100 μm and 150 μm, between about 150 μm and 200 μm, between about 200 μm and 250 μm, between about 250 μm and 300 μm, between about 300 μm and 350 μm, between about 350 μm and 400 μm, between about 400 μm and 450 μm, and/or between about 450 μm and 500 μm.

A predefined thickness of a porous layer, e.g., a porous metal layer according to the teachings of the present disclosure can range from a few micrometers thick to several hundred micrometers. For example, an average thickness of a low temperature sintered copper-copper formate slurry layer can be between about 1 μm and about 500 μm. In some variations, an average thickness of a low temperature sintered copper-copper formate slurry layer is between about 10 μm and about 30 μm, between about 30 μm and about 50 μm, between about 50 μm and about 75 μm, between about 75 μm and about 100 μm, between about 100 μm and about 150 μm, between about 150 μm and about 200 μm, between about 200 μm and about 250 μm, between about 250 μm and about 300 μm, between about 300 μm and about 350 μm, between about 350 μm and about 400 μm, between about 400 μm and about 450 μm, and/or between about 450 μm and about 500 μm.

As observed in FIG. 9A, the sintered copper-copper formate slurry layer 120 includes clusters or globs (i.e., accumulations) 121 of copper formate and an upper layer 124 of copper formate is delaminated (separated) from an underlying layer 126 of sintered copper particles. Accordingly, it should be understood that the sintered copper-copper formate slurry layer 120 is generally non-uniform with an uneven distribution of copper particles, a large variation in pore size between the copper particles, and with a rough outer (+z direction) surface as discussed in greater detail below.

In contrast, the sintered copper-copper formate slurry layer 140 shown in FIG. 9B with an upper (+z direction) delaminated layer of copper formate separated from an underlying (−z direction) layer of sintered copper particles and has only a small amount (less than 10% by volume) of volume excess reduced copper formate 143. Accordingly, it should be understood that the sintered copper-copper formate slurry layer 140 is generally uniform with an even distribution of copper particles, a small variation in pore size between the copper particles, and a smooth outer (+z direction) surface as discussed in greater detail below. In some variations, and as observed from FIG. 9B, the sintered copper-copper formate slurry layer 140 has less than 10% by volume excess reduced copper formate 143, e.g., less than 5% by volume excess reduced copper formate 143. And in some variations, the sintered copper-copper formate slurry layer 140 has less than 2% by volume excess reduced copper formate 143, e.g., less than 1% by volume excess reduced copper formate 143.

The sintered copper-copper formate slurry layer 140 is formed from a copper-copper formate slurry that is synthesized by mixing copper formate powder with isopropanolamine at a 1:6 weight ratio to form a copper formate-solvent solution. The copper formate-solvent solution is subjected to vacuum filtration through a filter with an average pore diameter of 100 μm to form a refined copper formate-solvent solution. And the refined copper formate-solvent solution is mixed with copper particles having an average article diameter between about 10 μm and 20 μm to form a copper-copper formate slurry. The copper-copper formate slurry is then applied to the substrate 142 (i.e., to the interface layer 141) using a doctor blade to form a copper-copper formate slurry layer. The copper-copper formate slurry layer is then heated in the range between 100 °C and 120 °C for one hour for solvent evaporation and then at 150 °C for two hours in a tube furnace with flowing argon (or nitrogen) to reduce the copper formate to copper and form bonds between adjacent copper particles. And while the copper copper formate slurry layer was applied to the substrate 142 using a doctor blade, the copper-copper formate slurry layer may also be applied using other techniques such as additive manufacturing (3D printing), molding, casting, extrusion, among others.

Still referring to FIG. 9B, in some variations, the bonding interface layer 141 is included to enhance the bonding strength between the sintered copper-copper formate slurry layer 140 and the substrate 142. And while the bonding interface layer 141 shown in FIG. 9B was applied via an electrodeposition technique, other techniques can be used to apply or form the bonding interface layer 141 on the substrate such as physical vapor deposition (PVD) techniques, chemical vapor deposition (CVD) techniques, among others.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modification and variations come within the scope of the appended claims and their equivalents.

### Example Clauses

Implementation examples are described in the following numbered clauses:
Clause 1: An electronic assembly comprising a printed circuit board (PCB), the PCB comprising a PCB surface; one or more heat generating devices coupled to the PCB surface, the one or more heat generating devices separated from one another by an insulation layer; and PCB trace connected to at least one of the one or more heat generating devices; and a cooling plate directly coupled to the PCB, the cooling plate comprising a porous layer directly coupled to at least one portion of the PCB; and a covering cap, wherein the electronic assembly is configured to passively transfer heat from the heat generating devices to the covering cap.
Clause 2: The electronic assembly of Clause 1, wherein the insulation layer comprises silicone.
Clause 3: The electronic assembly of any of any of Clauses 1-2, wherein the covering cap is a metallic cap.
Clause 4: The electronic assembly of any of Clauses 1-3, further comprising a thermal interface layer coupled to a top surface of the covering cap; and an air external cooler coupled to the thermal interface layer.
Clause 5: The electronic assembly of any of Clauses 1-4, wherein the one or more heat generating devices comprise low temperature devices and high temperature devices.
Clause 6: The electronic assembly of any of Clauses 1-5, wherein the covering cap comprises an internal porous layer.
Clause 7: The electronic assembly of any of Clauses 1-6, wherein the internal porous layer is coupled to the internal porous layer to form an enclosed volume.
Clause 8: The electronic assembly of any of Clauses 1-7, wherein the enclosed volume comprises a thermal coolant.
Clause 9: The electronic assembly of any of Clauses 1-8 wherein the thermal coolant is dielectric.
Clause 10: The electronic assembly of any of Clauses 1-9, wherein the covering cap is coupled to the PCB surface via a copper patterning.
Clause 11: The electronic assembly of any of Clauses 1-10, wherein the covering cap is coupled to the PCB surface by sintering the covering cap to copper patterning on the PCB surface.

Clauses 1-12: The electronic assembly of any of Clauses 1-11, wherein the one or more heat generating devices comprise low temperature devices and high temperature devices.

Clause 13: A method for a low temperature porous layer creation process comprising mixing a metal formate with a solvent to form a metal formate solution; adjusting a metal formate concentration in the metal formate solution; collecting a refined metal formate solution; mixing the refined metal formate solution with metal particles to form a metal particle slurry; applying the metal particle slurry to a substrate; and sintering the metal particle slurry onto the substrate.

Clause 14: The method of Clause 13, wherein the sintering occurs at a temperature that does not exceed 300 degrees Celsius.

Clause 15: The method of any of Clauses 13-14, wherein the sintering forms a copper cap with an internal wick layer.

Clause 16: The method of any of Clauses 13-15, wherein the method further comprises sintering the copper cap to copper patterning on a printed circuit board surface.

Clause 17: An integrated printed circuit board (PCB) cooling plate comprising a porous layer directly coupled to one or more heat generating devices, wherein the porous layer is formed by a low temperature porous layer creation process.

Clause 18: The integrated PCB cooling plate of Clause 17, wherein the low temperature porous layer creation process comprises mixing a metal formate with a solvent to form a metal formate solution; adjusting a metal formate concentration in the metal formate solution; collecting a refined metal formate solution; and mixing the refined metal formate solution with metal particles to form a metal particle slurry; applying the metal particle slurry to a substrate; and sintering the metal particle slurry onto the substrate.

Clause 19: The integrated PCB cooling plate of Clause 17, wherein the sintering of the metal particle slurry occurs at a temperature that does not exceed 300 degrees Celsius.

Clause 20: The integrated PCB cooling plate of Clause 17, wherein the integrated PCB cooling plate comprises a PCB surface, wherein the one or more heat generating devices are coupled to the PCB surface; an insulation layer, wherein the one or more heat generating devices are separated from one another by the insulation layer; PCB trace connected to at least one of the one or more heat generating devices; and a covering cap is directly coupled to the porous layer, wherein the covering cap is coupled to the PCB surface.

Clause 21: One or more processing systems, comprising: one or more memories comprising computer-executable instructions; and one or more processors configured to execute the computer-executable instructions and cause the one or more processing systems to perform a method in accordance with any one of Clauses 1-20.

Clause 22: One or more processing systems, comprising means for performing a method in accordance with any one of Clauses 1-20.

Clause 23: One or more non-transitory computer-readable media comprising instructions that, when executed by one or more processors of a computing system, cause the computing system to perform the operations of any one of Clauses 1-20.

Clause 24: One or more computer program products embodied on one or more computer-readable storage media comprising code for performing a method in accordance with any one of Clauses 1-20.

### Additional Considerations

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented, or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, unless stated otherwise, the term “or” is used in an inclusive sense. This inclusive usage of or is equivalent to “and/or”. Thus, when options are delineated using “or” it permits the selection of one or more of the enumerated options concurrently. For example, if the document stipulates that a component may comprise option A or option B, it shall be understood to mean that the component may comprise option A, option B, or both option A and option B, and does not mean, unless stated expressly that the component includes either option A or option B. This inclusive interpretation ensures that all potential combinations of the options are permissible, rather than restricting the choice to a singular, exclusive option.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the embodiments shown herein but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. An electronic assembly comprising:
a printed circuit board (PCB), the PCB comprising:
a PCB surface;
one or more heat generating devices coupled to the PCB surface, the one or more heat generating devices separated from one another by an insulation layer; and
PCB trace connected to at least one of the one or more heat generating devices; and
a cooling plate directly coupled to the PCB, the cooling plate comprising:
a porous layer directly coupled to at least one portion of the PCB; and
a covering cap, wherein the electronic assembly is configured to passively transfer heat from the heat generating devices to the covering cap.

2. The electronic assembly of claim 1, wherein the insulation layer comprises electrically insulating material.

3. The electronic assembly of claim 1, wherein the covering cap is a metallic cap.

4. The electronic assembly of claim 1, further comprising:
a thermal interface layer coupled to a top surface of the covering cap; and
an air external cooler coupled to the thermal interface layer.

5. The electronic assembly of claim 1, wherein the one or more heat generating devices comprise low temperature devices and high temperature devices.

6. The electronic assembly of claim 1, wherein the porous layer being directly coupled to the at least one portion of the PCB comprises at least a portion of the porous layer being a coating on the at least one portion of the PCB, wherein the coating comprises a uniform coating or a patterned coating.

7. The electronic assembly of claim 1, wherein the covering cap comprises an internal porous layer.

8. The electronic assembly of claim 7, wherein the internal porous layer is coupled to the internal porous layer to form an enclosed volume.

9. The electronic assembly of claim 8, wherein the enclosed volume comprises a thermal coolant.

10. The electronic assembly of claim 9 wherein the thermal coolant is dielectric.

11. The electronic assembly of claim 1, wherein the covering cap is coupled to the PCB surface via a copper patterning.

12. The electronic assembly of claim 11, wherein the covering cap is coupled to the PCB surface by sintering the covering cap to copper patterning on the PCB surface.

13. The electronic assembly of claim 1, wherein the cooling plate is configured to passively transfer heat from the heat generating devices to the covering cap.

14. A method for a low temperature porous layer creation process comprising:
mixing a metal formate with a solvent to form a metal formate solution;
adjusting a metal formate concentration in the metal formate solution;
collecting a refined metal formate solution;
mixing the refined metal formate solution with metal particles to form a metal particle slurry;
applying the metal particle slurry to a substrate; and
sintering the metal particle slurry onto the substrate.

15. The method of claim 14, wherein the sintering of the metal particle slurry occurs at a temperature that does not exceed 300 degrees Celsius.

16. The method of claim 14, wherein the sintering forms a copper cap with an internal wick layer.

17. The method of claim 16, wherein the method further comprises sintering the copper cap to copper patterning on a printed circuit board surface.

18. An integrated printed circuit board (PCB) cooling plate comprising a porous layer directly coupled to one or more heat generating devices, wherein the porous layer is formed by a low temperature porous layer creation process.

19. The integrated PCB cooling plate of claim 18, wherein the low temperature porous layer creation process comprises:
mixing a metal formate with a solvent to form a metal formate solution;
adjusting a metal formate concentration in the metal formate solution;
collecting a refined metal formate solution;
mixing the refined metal formate solution with metal particles to form a metal particle slurry;
applying the metal particle slurry to a substrate; and
sintering the metal particle slurry onto the substrate.

20. The integrated PCB cooling plate of claim 18, wherein the integrated PCB cooling plate comprises:
a PCB surface, wherein one or more heat generating devices are coupled to the PCB surface;
an insulation layer, wherein the one or more heat generating devices are separated from one another by the insulation layer;
PCB trace connected to at least one of the one or more heat generating devices; and
a covering cap is directly coupled to the porous layer, wherein the covering cap is coupled to the PCB surface.
